(19) United States
(12) Patent Application Publication
(10) Pub. No.: US 2006/0003565 A1
(43) Pub. Date: Jan. 5, 2006

(54) Method and apparatus for manufacturing semiconductor device

(75) Inventor: Masaru Sasaki, Amagasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/202,276

(22) Filed: Aug. 12, 2005

Related U.S. Application Data
(63) Continuation-in-part of application No. PCT/JP04/01539, filed on Feb. 13, 2004.

(30) Foreign Application Priority Data
Feb. 13, 2003 (JP) 2003-035075

(51) Int. Cl. H01L 21/469; C23C 16/00

(52) U.S. Cl. 438/592; 438/788; 118/715

(57) ABSTRACT

A semiconductor manufacturing apparatus has a first layer made of a film having a different component from a film having tungsten and a second layer made of the film having tungsten. The first layer is a polysilicon layer, and the second layer is a tungsten layer. On an exposed surface of the first layer, an oxide film is formed by performing a plasma processing using Ar gas, O₂ gas and H₂ gas. During the plasma processing, the Ar gas, O₂ gas and H₂ gas are used at a predetermined flow rate ratio. Consequently, a selective oxidation of the polysilicon layer can be conducted without oxidizing the tungsten layer.

This application is a Continuation-In-Part Application of PCT International Application No. PCT/JP2001/001539 filed on Feb. 13, 2004, which designated the United States.

### FIELD OF THE INVENTION

The present invention relates to a method and apparatus for processing a semiconductor substrate by using a plasma; and more particularly, to a method and apparatus for forming a gate electrode of a transistor, which is formed by using same.

### BACKGROUND OF THE INVENTION

Recently, for the purposes of providing high speed transistors and achieving a scale-down of devices and the like, gate oxide films or the like have become ultra-thin. In general, a gate of a transistor is formed in an order of a well (doping region, diffusion region), gate insulating film, and gate electrode; After a gate electrode is formed, a wet etching process is performed on a side of the gate electrode. As a result, the gate electrode becomes exposed, and this causes a generation of electric field concentration in the exposed area when a voltage is applied to the gate electrode. Such electric field concentration results in problems such as increased leakage current and the like. To solve this problem, an insulating film is usually formed on the exposed area of the gate electrode.

As for a gate electrode, polysilicon has been commonly used. However, since polysilicon has a high sheet resistance, a low-resistance metal is laminated thereon. As for the metal to be laminated, its choice is based on its adhesivity and processability with silicon oxide film or silicon itself; hence, refractory metals such as tungsten or the like, or silicide thereof are used. When forming an insulating film on the side of a gate electrode, which has been exposed due to etching, a thermal oxidation processing is generally performed at high temperature of 800° C. or higher.

Since, however, tungsten becomes rapidly oxidized at about 300° C., the resistance of the tungsten layer is increased when the thermal oxidation processing is performed on the gate electrode. As a result, the resistance of the gate electrode is increased. Further, tungsten would react with polysilicon to disperse diffusion barrier layer of tungsten nitride (WN), resulting in an increase of resistivity.

In view of the above issues, to prevent an oxidation of tungsten when performing a thermal oxidation processing, it has been considered to oxidize a side of a gate electrode in a high temperature reducing atmosphere. However, in that case, it has been observed that tungsten becomes sublimated to grow abnormally in a needle-like shape. Further, the substrate thereof is contaminated to lower the reliability. Still further, in P-channel transistors, a rapid diffusion of boron can be triggered.

Still further, it takes relatively a long time to perform the thermal oxidation processing itself. This factor interferes with improving the productivity by raising the throughput.

As for a method of forming an oxide film other than the thermal oxidation processing, there has been proposed a method for forming an oxide film by using plasma, as disclosed in, e.g., Japanese Patent Laid-open Application No. H11-293470. In this method, silicon containing gas and oxygen containing gas are introduced into the processing chamber to generate plasma thereof, and therefore, a silicon oxide film is formed on the substrate. Then, a hydrogen gas is introduced into the processing chamber to produce a plasma of hydrogen containing gas, so that the substrate having thereon the silicon oxide film is processed. In this manner, a superior film quality comparable to a thermal oxide film can be obtained.

### SUMMARY OF THE INVENTION

It is, therefore, an object of the present invention to provide a method and apparatus capable of performing a selective oxidation process on layers such as polysilicon and the like, without oxidizing tungsten or tungsten silicide layers.

In accordance with one aspect of the present invention, there is provided a method for manufacturing a semiconductor device by forming on a semiconductor substrate a film having tungsten and a film having a different component from the film having tungsten, the method including the steps of: forming on the semiconductor substrate a first layer made of the film having a different component from the film having tungsten; forming on the semiconductor substrate a second layer made of the film having tungsten; and forming an oxide film on an exposed surface of the first layer by performing a plasma processing Ar gas and O₂ gas.

In accordance with another aspect of the present invention, there is provided a method for manufacturing a semiconductor device by forming on a semiconductor substrate a film having tungsten and a film having a different component from the film having tungsten, the method including the steps of: forming on the semiconductor substrate a first layer made of the film having a different component from the film having tungsten; forming on the semiconductor substrate a second layer made of the film having tungsten; and forming an oxide film on an exposed surface of the first layer by performing a plasma processing using Ar gas, O₂ gas and H₂ gas, Wherein, during the plasma processing, the Ar gas, O₂ gas and H₂ gas are used at a predetermined flow rate ratio.

In accordance with still another aspect of the present invention, there is provided a semiconductor manufacturing apparatus for manufacturing a semiconductor device having a first layer formed on a semiconductor substrate, which is made of a film having a different component from a film having tungsten, and a second layer made of the film having tungsten, the apparatus including: a processing vessel accommodating therein the semiconductor substrate as an object to be processed; a gas supply unit for supplying into the processing vessel a gas for use in a plasma processing; an electromagnetic wave generation unit for generating an electromagnetic wave used for producing a plasma in the processing vessel; a dielectric plate airtightly disposed at an upper portion in the processing vessel; and an antenna disposed on the dielectric plate, the electromagnetic wave being introduced through the antenna and the dielectric plate into the processing vessel, wherein an oxide film is formed selectively on an exposed surface of the first layer by performing the plasma processing.

In the aforementioned aspects of the present invention, it is preferable to use an oxygen gas and a hydrogen gas at a predetermined flow rate ratio, during the plasma processing. By doing this, the selectivity for forming the oxide film can be improved. To elaborate, the first layer can be oxidized securely without oxidizing the second layer.

The present invention may be applied for forming a gate electrode of a transistor, and a plasma oxidation processing is performed on a side of the gate electrode.

### BRIEF DESCRIPTION OF THE DRAWINGS

The above and other objects and features of the present invention will become apparent from the following description of preferred embodiments given in conjunction with the accompanying drawings, in which:

FIG. 1 shows a schematic view (a cross sectional view) of an exemplary configuration of a plasma processing apparatus in accordance with the present invention;

FIGS. 2A and 2B schematically show that an oxide film is selectively formed on a gate electrode in accordance with the present invention; FIG. 2A represents the state before plasma oxidation processing; and FIG. 2B represents the state after plasma oxidation processing;

FIGS. 3A and 3B schematically show the shape of the gate electrode after the oxide film is formed on a side of a laminated gate electrode: FIG. 3A represents a case of employing plasma oxidation processing; and FIG. 3B represents a comparative case of employing high-temperature oxidation;

FIGS. 4A and 4B show a graph representing variations in oxidation of tungsten layer depending on plasma oxidation processing: FIG. 4A is a status of the oxygen line profile before plasma processing; and FIG. 4B is a status of the oxygen line profile after plasma processing;

FIG. 5 is a graph showing tungsten's oxidation level when hydrogen gas is added and its flow rate is varied;

FIG. 6 is a graph showing tungsten sheet resistance variations depending on oxidation processing method; and

FIG. 7 is a graph showing tungsten sheet resistance variations due to plasma oxidation, as a flow rate of hydrogen gas is varied.

### DETAILED DESCRIPTION OF THE PREFERRED EMBODIMENT

Preferred embodiments of the present invention will be described in detail with reference to the accompanying drawings.

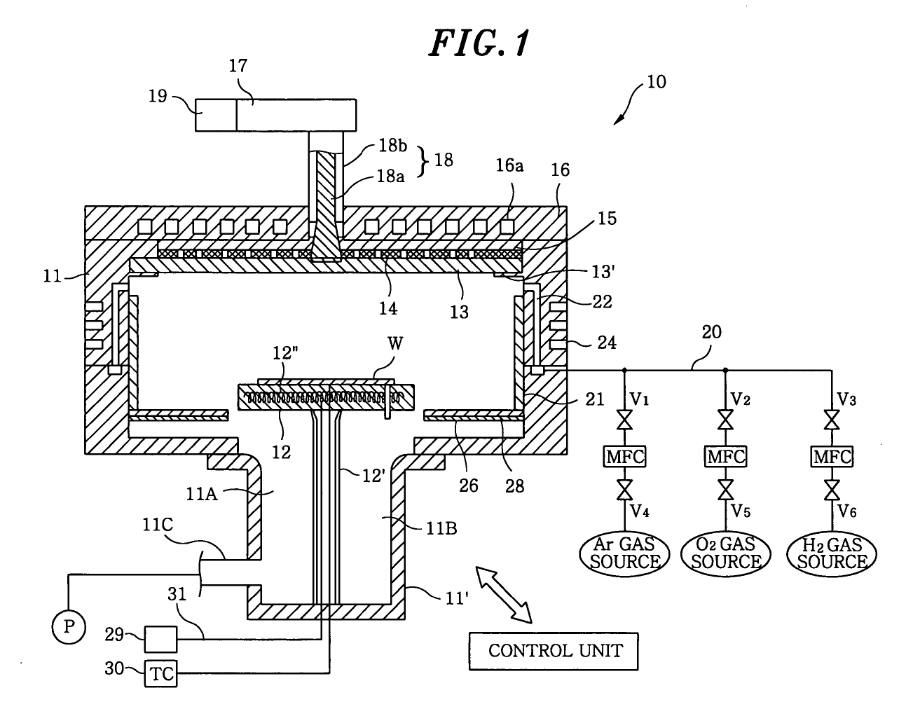

FIG. 1 shows a schematic view (a cross sectional view) of an exemplary configuration of a plasma processing apparatus 10 in accordance with a preferred embodiment of the present invention. The plasma processing apparatus 10 includes a processing vessel 11, an electromagnetic wave generation unit, a gas exhaust system and a gas supply system. Further, a control unit controls operations of the electromagnetic wave generation unit, the gas exhaust system and the gas supply system.

The processing vessel 11 has therein a substrate supporting table 12 for supporting a silicon wafer W as a substrate to be processed. Gas in the processing vessel 11 is exhausted through a gas exhaust pump P via a gas exhaust pipe 11C out of exhaust ports 11A and 11B in an exhaust chamber 11′. Further, the substrate supporting table 12 has therein a resistance variable heater 12″ to serve as a heater for heating the silicon wafer W, and a heater power supply 29 is connected to the resistance variable heater 12″ through a power supply line 31. The resistance variable heater 12″ is controlled by a thermocouple 30 for measuring a temperature to heat the substrate supporting table 12 and hence the wafer W. The substrate supporting table 12 is supported by a cylindrical supporter 12′ made of ceramic such as AlN, Al₂O₃ or the like. Around the substrate supporting table 12, there is disposed a gas baffle plate (partition plate) 26 made of aluminum. On the top surface of the gas baffle plate 26, a quartz cover 28 is provided.

Above the processing vessel 11, an opening is formed to face the silicon wafer W on the substrate supporting table 12. The opening is blocked by a dielectric plate 13 made of quartz or Al₂O₃. The dielectric plate 13 is supported by a supporting part 13′ and an inside of the processing vessel 11 is airtightly sealed by using O-ring. A planar antenna 14 is disposed on the dielectric plate 13 (on the outer side of the processing vessel 11). In the planar antenna 14, a plurality of slots is formed for transmitting therethrough electromagnetic waves supplied from a waveguide. Further above the planar antenna 14 (on the outer side thereof), a wavelength shortening plate 15 (slow wave) and a waveguide 18 are disposed. A cooling plate 16 is disposed on the outer side of the processing vessel 11 to cover an upper portion of the wavelength shortening plate 15. Coolant channels 16a through which coolant circulates are provided inside the cooling plate 16.

At an inner sidewall of the processing vessel 11, a gas supply port 22 is provided for introducing gas when performing a plasma processing. Additional gas supply ports 22 can be provided for each gas to be introduced. In this case, a mass flow controller (MFC) as flow rate adjusting means is provided for each gas supply port. Otherwise, it is acceptable to have a single nozzle as for the gas supply port 22 and to have introduced gas to be mixed in advance. Here, gas supplied from Ar gas source, O₂ gas source or H₂ gas source is introduced into the gas supply port 22 through a gas supply line 20. The flow rate of introduced gas is regulated at a mixing step by flow rate adjusting valves (V1-V6) or the like. Further, in the inner wall of the processing vessel 11, a coolant path 24 is formed to surround the entire vessel.

The electromagnetic wave generation includes an electromagnetic wave generator 19 and waveguides 17 and 18. The electromagnetic wave generator 19 generates electromagnetic waves of several gigahertz (e.g., 2.45 GHz) to ignite a plasma. Microwaves generated by the electromagnetic wave generator 19 radially and uniformly propagate towards the planar antenna 14 through the rectangular waveguide 17 and the coaxial waveguide 18 to be introduced into the processing vessel 11 via the slow wave plate 15, the slots of the planar antenna 14 and the dielectric plate 13. The coaxial waveguide 18 is formed of an inner conductor 18a and an outer conductor 18b.

When forming a gate electrode of a semiconductor device, first a well region is formed in a silicon wafer. Then, a gate oxide film is formed on the silicon wafer by performing a plasma-oxidation or thermal-oxidation processing. Thereafter, polysilicon is formed by using a CVD process. For purpose of reducing resistance of the gate electrode, a refractory electrode material having a resistivity lower than polysilicon is laminated on polysilicon, to thereby fabricate a laminated gate electrode. As for the refractory electrode material, tungsten can be used. Then, a wet etching processing is performed on a side of the gate electrode. Since the native oxide film or contaminations remain at the side of the gate electrode, the wet etching processing may be preferably performed to remove them by using HF solution.

When side and lower portions of the laminated gate electrode are left exposed, problems such as an increase in leakage current and the like due to electric field concentration occur. Thus, in the present invention, an insulating film is formed on the side and lower portions of the gate electrode by performing plasma processing. To elaborate, a silicon wafer W having insulating film with etched sides is set inside the processing vessel 11 of the plasma processing apparatus 10. Thereafter, the inside of the processing vessel 11 is exhausted through the exhaust ports 11A and 11B to be set at predetermined processing pressure. Next, nonreactive and oxygen gases are supplied from the gas supply port 22. In addition, a hydrogen gas is introduced to increase the selectivity of the oxidation processing (i.e., selectively oxidizing poly silicon without oxidizing tungsten). In this case, a gaseous mixture of oxygen and hydrogen gases, which have been mixed at a predetermined flow rate ratio, is introduced.

Meanwhile, microwaves of several GHz (2.45 GHz) frequency that have been generated by the electromagnetic wave generator 19 are supplied into the processing vessel 11 through the waveguides 17 and 18. The microwaves are introduced into the processing vessel 11 through the planar antenna 14 and the dielectric plate 13. By the microwaves, a plasma is formed to produce radicals. When performing a plasma processing as such, the wafer temperature is 400° C. or less. When hydrogen gas is added, tungsten oxidation is suppressed while Si is selectively oxidized. A high-density plasma, produced through excitation by microwaves in the processing vessel 11, forms an oxide film on the silicon wafer W. Thus, the temperature of the substrate may be preferably 400° C. or less, and more preferably, 300° C. or less.

As explained above, tungsten oxidation is started and progressed rapidly if temperature surpasses about 300° C. In the present embodiment, tungsten is subjected to oxidation processing at 300° C. or below, and WSi at 400° C. or below. As a result, tungsten is not oxidized, and polysilicon is selectively oxidized.

In the present embodiment, when hydrogen gas is added, although oxygen gas is simultaneously added, as the flow rate ratio of hydrogen gas becomes larger, the reducibility of the atmosphere increases since there are many hydrogen radicals. As a result, the selectivity for target layers to be oxidized is enhanced. Accordingly, the selectivity for oxidizing only polysilicon without oxidizing tungsten is improved. Further, using other refractory electrode materials other than tungsten has the same effect.

### EXAMPLE

Hereinafter, an example of the present invention will be explained by illustrating a gate electrode formed on an MOS transistor of a semiconductor device.

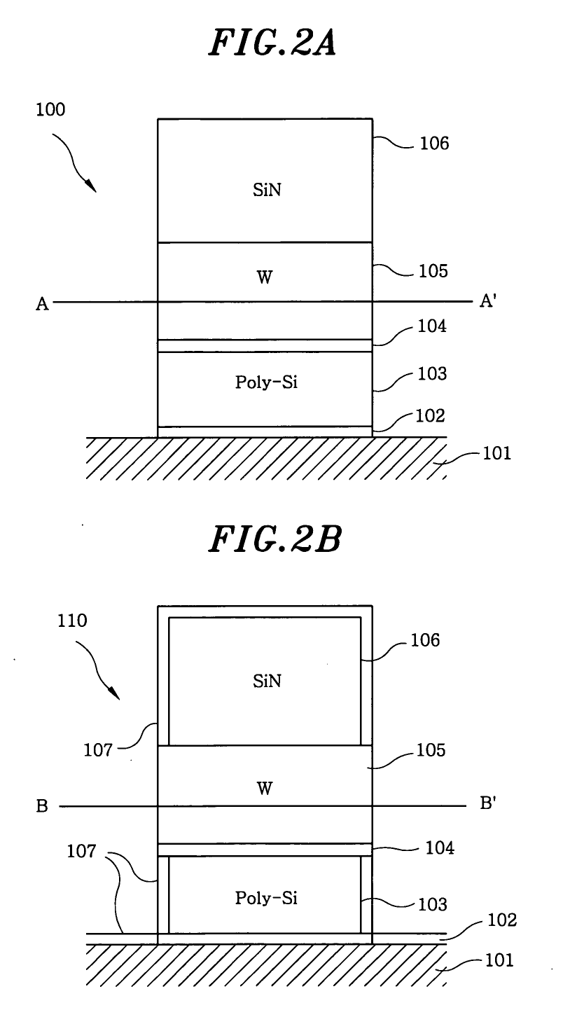

FIG. 2 schematically shows that an oxide film is selectively formed on a gate electrode in accordance with the present example. FIG. 2A shows a gate electrode 100 after etching. The reference number 101 indicates a silicon wafer W. In the silicon wafer 101, a well region (diffusion region) wherein P⁺ type or N⁺ type impurity is doped is formed. A gate oxide film 102 is formed on the silicon wafer 101 by thermal oxidation processing. On the gate oxide film 102, a polysilicon electrode layer 103 (a first electrode layer) is formed by laminating polysilicon by a CVD process. To lower resistivity of the gate electrode 100, as a refractory electrode material, for example, a tungsten layer 105 (a second electrode layer) is formed on the polysilicon layer by a sputtering process or CVD. Further, before forming the tungsten layer 105, a conductive barrier layer 104 is formed in advance on the polysilicon electrode layer 103 to prevent the interface of the tungsten layer 105 from silicidization. In this example, tungsten nitride is employed as the barrier layer 104. On the uppermost layer on the tungsten layer 105, an insulating layer made of a silicon nitride layer 106 serving as an etching mask or preventing the oxidation of W is formed.

Subsequently, the tungsten (W) layer 105, the tungsten nitride (WN) layer 104, and the polysilicon electrode layer 103 are etched using the silicon nitride layer 106 as an etching mask to form a gate electrode. Side of the gate electrode and active region of the substrate are etched off, and thus, being exposed.

Etching residues and native oxide film remain at side of the gate electrode and active region of the substrate, which are preferably removed by using HF solution.

Substrate of exposed side and diffusion region of the gate electrode 100 are loaded into the plasma processing apparatus 10. Ar gas and O₂ gas are supplied thereinto, so that, the side of polysilicon is selectively oxidized without oxidizing W. In this case, hydrogen is added to increase the selectivities of polysilicon and tungsten (W) during oxidation processing, to thereby fabricate a gate electrode 110 as shown in FIG. 2B. At this time, no oxide film is formed on the barrier layer 104.

Further, instead of the tungsten layer 105, it is acceptable to use other refractory electrode materials, e.g., molybdenum, tantalum, titanium, silicides thereof, alloys thereof and the like.

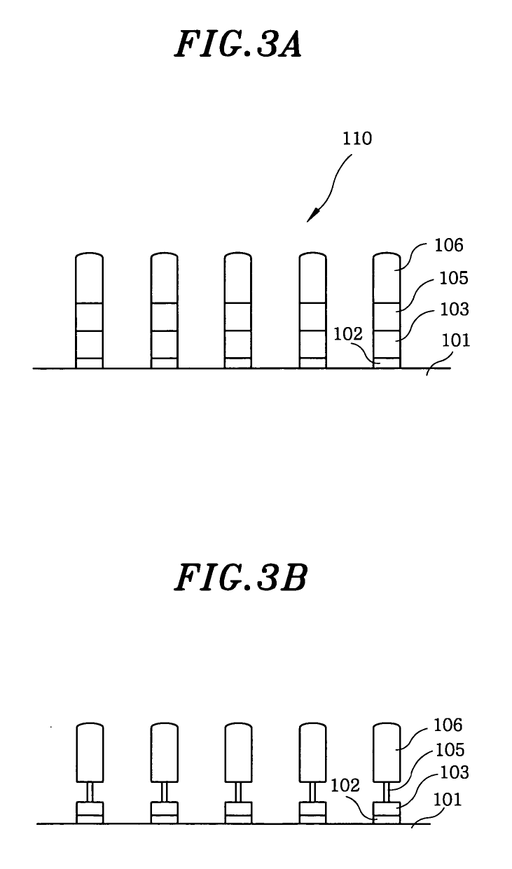

FIG. 3A shows the gate electrode 110 wherein oxide films are formed on sides of the gate electrodes of the MOS transistor by performing the plasma processing in accordance with the present example. In such a laminated gate electrode, the thickness from the polysilicon layer 103 to the silicon nitride layer 106 is 250 nm. Here, temperature of the silicon substrate is 250° C., and processing time is 50 seconds. For comparison, FIG. 3B shows a case of employing thermal oxidation. Here, temperature of the silicon substrate is 400° C., and processing time is 110 seconds. As indicated clearly by the drawings, since the processing temperature is high in the case that employs thermal oxidation, tungsten is scattered as WOx gas obtained by reaction of W and O (disintegrate). From this scattering of tungsten, the substrate can be contaminated. As in this case where oxidation takes place at 250° C. for the silicon substrate, in accordance with the present example, this problem from tungsten scattering does not arise.

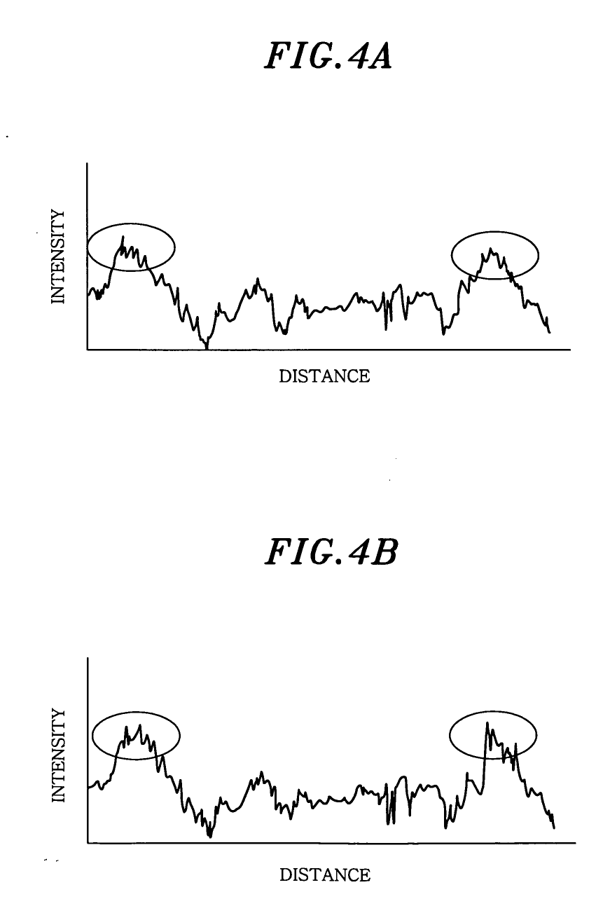

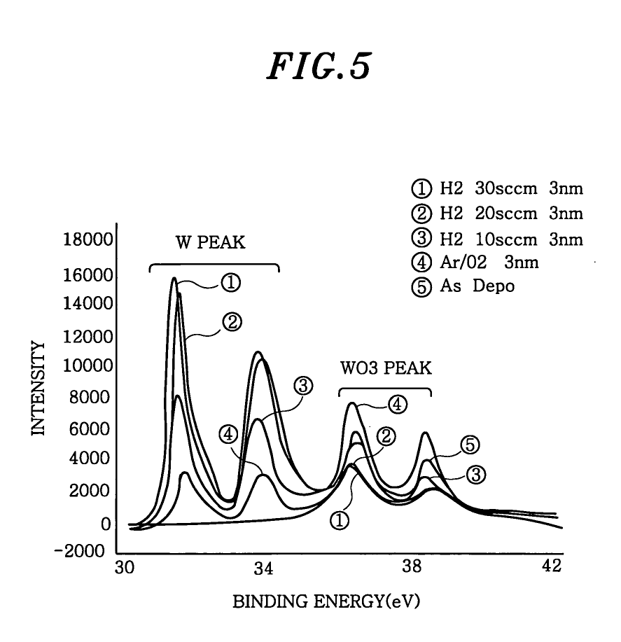

FIGS. 4A and 4B show variations in oxidation of the tungsten layer 105 depending on plasma oxidation processing. The plasma oxidation processing was performed on the gate electrode of FIG. 2 by using Ar gas and O₂ gas for 50 seconds of processing time at lower temperature of 250° C. The oxygen line profile was measured by the EELS (Electron Energy Loss Spectroscopy). FIG. 4A shows the status of the oxygen line profile before the plasma processing. The tungsten layer 105 was measured along the A-A′ cross section of FIG. 2A. Further, FIG. 4B shows the status of the oxygen line profile after the plasma processing. In the same manner, the tungsten layer 105 was measured along the B-B′ cross section of FIG. 2B. The vertical axis represents luminous intensity in proportion to the amount of oxygen. The horizontal axis represents the coordinate along A-A′ or B-B′ cross sectional line as a normalized unit. From these results, it can be demonstrated that the oxide film of the tungsten layer 105 is hardly changed before and after the plasma oxidation processing, and the oxidation of the tungsten layer 105 is negligible.

Next, in the gate electrode of the semiconductor device in accordance with the present example, oxide film thickness in the side of the polysilicon layer 103 was observed by a TEM before and after performing the plasma oxidation processing by using Ar gas and O₂ gas. As a result, while the thickness of oxide film on the side of the gate electrode, which has been subjected to etching and wet cleaning, is about 2.0 nm, after being subjected to low temperature plasma oxidation processing, the thickness of oxide film on the side of the gate electrode is about 3.3 nm. To elaborate, in accordance with the present example, the selectivity of oxide film for forming on the polysilicon layer is clearly demonstrated.

From the above results, it is observed that oxide film is selectively formed on polysilicon layer, and it is not formed additionally on the tungsten layer, in accordance with the present example. Further, the formation of oxide film may be controlled by conditions such as time, processing temperature and the like.

When performing the plasma oxidation processing on the exposed side of the gate electrode 100 of the MOS transistor with the aforementioned plasma processing apparatus 10, hydrogen gas can be supplied. This approach allows for a reducing environment to be developed when performing radical oxidation processing, so that the selectivity for polysilicon oxidization is further enhanced without oxidizing tungsten.

FIG. 5 shows the effects on oxidation levels of tungsten, measured by surface analysis using XPS, as hydrogen gas is added to Ar gas and O₂ gas and its flow rate is varied. The vertical axis represents peak intensities of W and WO₃, and the horizontal axis represents the binding energy. In the graph, \textcircled{1}, \textcircled{2} and \textcircled{3} are the cases where hydrogen gas is added at flow rates of 30, 20 and 10 sccm, respectively. For comparison, \textcircled{4} is a case where only argon and oxygen are added, and \textcircled{5} is a case where W is subjected to an as-depo (oxidation processing). For \textcircled{1}, \textcircled{2}, \textcircled{3} and \textcircled{4}, oxide film thicknesses on Si substrates are the same, i.e., 3 nm. As shown by these results, the intensity around the binding energy range 31-34 eV, which represents the tungsten peak, becomes higher as the flow rate of hydrogen gas is raised. In comparison, the intensity around 35-39 (eV) binding energy range, i.e., the peak of tungsten oxide, is high for processing methods without using hydrogen gas as in \textcircled{4} or \textcircled{5}. Therefore, if the flow rate of hydrogen gas increases, oxidation of W is suppressed since W is reduced due to hydrogen radicals. And thus, the level of tungsten oxidization becomes less.

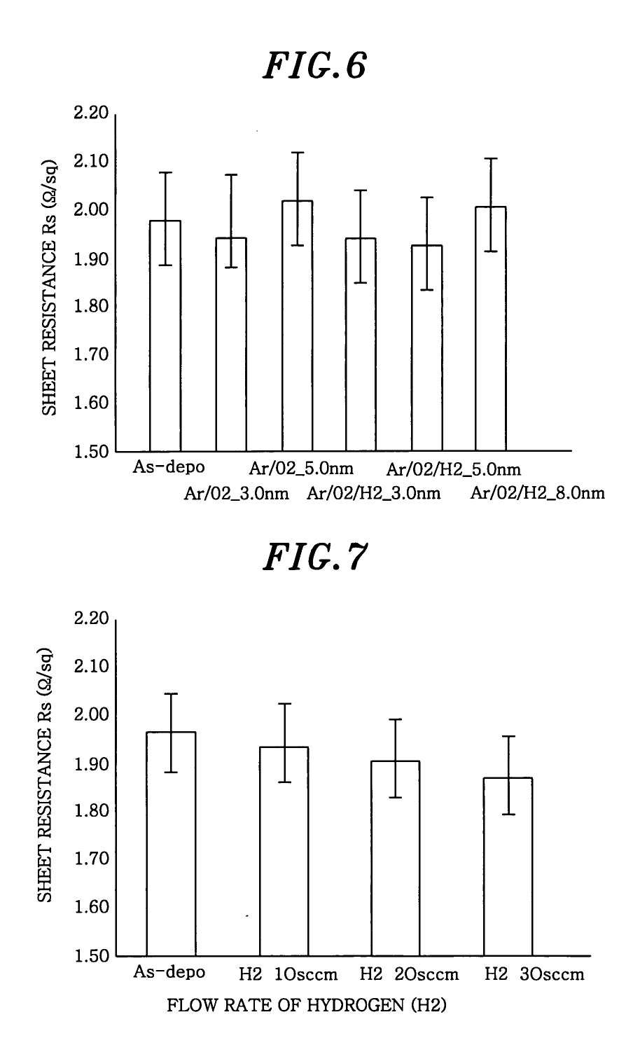

FIG. 6 shows a result obtained by: first, preparing a sample having a thin tungsten film formed on a silicon substrate; and then measuring the variations in sheet resistance depending on the oxidation processing method employed. The vertical axis represents the value of sheet resistance, and its unit is Ω/sq. For comparison, a case of As-depo and a case of plasma oxidation process by oxygen and argon are also included. “Ar/O₂ 3.0 nm” indicates plasma oxidation processing wherein radicals are produced by argon and oxygen, and the thickness of oxide film on the Si substrate is 3 nm. Similarly, “Ar/O₂ 5.0 nm” indicates plasma oxidation processing wherein radicals are produced by argon and oxygen, and the thickness of oxide film on the Si substrate is to 5 nm. Further, “Ar/O₂/H₂ 3.0 nm” indicates plasma oxidation processing wherein radicals are produced by argon, oxygen and hydrogen, and the thickness of oxide film on the Si substrate is 3 nm. Similarly, “Ar/O₂/H₂ 5.0 nm” indicates plasma oxidation processing wherein radicals are produced by argon, oxygen and hydrogen, and the thickness of oxide film on the Si substrate is to 5 nm. Still further, the flow rate ratio of Ar/O₂/H₂ gas in this example is 1000/10/10. It is preferable that a flow rate ratio of O₂/H₂ is 1 or greater and temperature of the substrate is 400° C. or less. Further, it is preferable that the ratio of H₂ flow rate to the total flow rate is greater than 0.98.

As can be seen from FIG. 6, if hydrogen gas is added while performing plasma oxidation processing, the sheet resistance is lowered regardless of the thickness of oxide film on the Si substrate, and this is a desirable effect. To elaborate, the surface of tungsten is reduced and this effectively prevents oxidation.

In FIG. 7, sheet resistance of thin tungsten film is measured by changing the flow rate of hydrogen gas, when forming by plasma oxidation an oxide film of 3 nm on the silicon substrate. For comparison, sheet resistance of the W subject to the As-depo is included as well. If the flow rate of hydrogen gas is raised, the sheet resistance of tungsten decreases. To elaborate, if the fraction of hydrogen gas is increased, the selectivity for oxidation is improved. By investigating different flow rate ratios by changing the fraction of hydrogen gas, an optimal condition for oxidizing polysilicon without tungsten oxidation can be determined.

While the invention has been shown and described with respect to the preferred embodiments, it will be understood by those skilled in the art that various changes and modifications may be made without departing from the spirit and scope of the invention as defined in the following claims. For example, here, the gate electrode formed by laminating polysilicon and tungsten has been explained. However, a single layer composed of tungsten, other refractory electrode materials or their silicides can also be employed. Further, besides a gate electrode of a transistor, the present invention can also be applied to various semiconductor fabrications wherein polysilicon layers or the like, except tungsten layers, should be selectively oxidized.

As explained thus far, to perform oxidation processing on the surfaces of a gate electrode and the like through plasma processing, layers such as polysilicon and the like can be selectively oxidized without oxidizing tungsten or tungsten silicide layer.

The method and apparatus for manufacturing the semiconductor device in accordance with the present invention can be used in the semiconductor manufacturing industry, for manufacturing semiconductor devices. Accordingly, the present invention has an industrial applicability.

While the invention has been shown and described with respect to the preferred embodiments, it will be understood by those skilled in the art that various changes and modifications may be made without departing from the spirit and scope of the invention as defined in the following claims.

What is claimed is:

1. A method for manufacturing a semiconductor device by forming on a semiconductor substrate a film having tungsten and a film having a different component from the film having tungsten, the method comprising the steps of:
forming on the semiconductor substrate a first layer made of the film having a different component from the film having tungsten;
forming on the semiconductor substrate a second layer made of the film having tungsten; and
forming an oxide film on an exposed surface of the first layer by performing a plasma processing using Ar gas and O₂ gas.

2. The method for manufacturing a semiconductor device of claim 1, wherein the semiconductor device is a transistor, and a gate electrode is formed by the first and the second layer.

3. The method for manufacturing a semiconductor device of claim 2, wherein the second layer is a tungsten layer or a tungsten silicide layer.

4. The method for manufacturing a semiconductor device of claim 3, wherein the plasma processing is performed at 400° C. or less.

5. The method for manufacturing a semiconductor device of claim 4, wherein the plasma processing is performed at 300° C. or less.

6. The method for manufacturing a semiconductor device of claim 3, wherein the first layer is a polysilicon layer.

7. A method for manufacturing a semiconductor device by forming on a semiconductor substrate a film having tungsten and a film having a different component from the film having tungsten, the method comprising the steps of:
forming on the semiconductor substrate a first layer made of the film having a different component from the film having tungsten;
forming on the semiconductor substrate a second layer made of the film having tungsten; and
forming an oxide film on an exposed surface of the first layer by performing a plasma processing using Ar gas, O₂ gas and H₂ gas,
Wherein, during the plasma processing, the Ar gas, O₂ gas and H₂ gas are used at a predetermined flow rate ratio.

8. The method for manufacturing a semiconductor device of claim 7, wherein a flow rate ratio of O₂/H₂ is 1 or greater.

9. The method for manufacturing a semiconductor device of claim 7, wherein a ratio of flow rate of H₂ to a total flow rate of Ar+O₂+H₂ is 0.98 or greater.

10. The method for manufacturing a semiconductor device of claim 7, wherein the semiconductor device is a transistor, and a gate electrode is formed by the first and the second layer.

11. The method for manufacturing a semiconductor device of claim 10, wherein the second layer is a tungsten layer or a tungsten silicide layer.

12. The method for manufacturing a semiconductor device of claim 11, wherein the plasma processing is performed at 300° C. or less in case the second layer is a tungsten layer, or at 400° C. or less in case the second layer is a tungsten silicide layer.

13. The method for manufacturing a semiconductor device of claim 11, wherein the first layer is a polysilicon layer.

14. A semiconductor manufacturing apparatus for manufacturing a semiconductor device including a first layer formed on a semiconductor substrate, which is made of a film having a different component from a film having tungsten, and a second layer made of the film having tungsten, the apparatus comprising:
a processing vessel accommodating therein the semiconductor substrate as an object to be processed;
a gas supply unit for supplying into the processing vessel a gas for use in a plasma processing;
an electromagnetic wave generation unit for generating an electromagnetic wave used for producing a plasma in the processing vessel;
a dielectric plate airtightly disposed at an upper portion in the processing vessel; and
an antenna disposed on the dielectric plate, the electromagnetic wave being introduced through the antenna and the dielectric plate into the processing vessel,
wherein an oxide film is formed selectively on an exposed surface of the first layer by performing the plasma processing.

15. The semiconductor manufacturing apparatus of claim 14, wherein the semiconductor device is a transistor, and a gate electrode is formed by the first and the second layer.

16. The semiconductor manufacturing apparatus of claim 15, wherein the second layer is a tungsten layer or a tungsten silicide layer.

17. The semiconductor manufacturing apparatus of claim 16, wherein the plasma processing is performed at 300° C. or less in case the second layer is a tungsten layer, or at 400° C. or less in case the second layer is a tungsten silicide layer.

18. The semiconductor manufacturing apparatus of claim 16, wherein the first layer is a polysilicon layer.

19. The semiconductor manufacturing apparatus of claim 14, wherein the antenna is of a planar antenna.

20. The semiconductor manufacturing apparatus of claim 14, wherein the electromagnetic wave is a microwave.

21. The semiconductor manufacturing apparatus of claim 14, wherein the dielectric plate is supported by a supporting part.

22. The semiconductor manufacturing apparatus of claim 14, wherein, in a wall of the processing vessel, a coolant path is formed.
